(19) United States
(12) Patent Application Publication
(10) Pub. No.: US 2024/0426410 A1
(43) Pub. Date: Dec. 26, 2024

(54) I-BRIDGE

(71) Applicant: Compart Systems Pte. Ltd., Singapore (SG)

(72) Inventors: Kim N. Vu, Yorba Linda, CA (US); John C. Lantz, Dallas, TX (US); Frederick Rezaei, Phoenix, AZ (US)

(21) Appl. No.: 18/755,289

(22) Filed: Jun. 26, 2024

Related U.S. Application Data
(60) Provisional application No. 63/523,163, filed on Jun. 26, 2023.

(51) Int. Cl. F16L 41/03; H01L 21/67

(52) U.S. Cl. CPC F16L 41/03; H01L 21/67017

(57) ABSTRACT

A delivery system can comprise a modular flow substrate comprising an i-Block and an i-Bridge. The i-Block can comprise a first i-Block conduit port, a second i-Block conduit port, a plurality of mounting apertures, a connection depression, at least one i-Block connection aperture and a fluid pathway extending between the first i-Block conduit port and the second i-Block conduit port. The i-Bridge can comprise an i-Bridge conduit port, a manifold connection conduit port, at least one connection aperture, at least one mounting aperture, a connection protrusion, and a fluid pathway extending between the i-Bridge conduit port and the manifold connection conduit port. The connection protrusion can be sized and configured to fit within the connection depression of the i-Block.

### FIELD OF THE DISCLOSURE

The present disclosure is directed to fluid delivery systems, and more particularly to extreme flow rate and/or high temperature surface mount fluid delivery systems for use in the semiconductor processing and petrochemical industries

### BACKGROUND OF THE ART

Fluid delivery systems are used in many modern industrial processes for conditioning and manipulating fluid flows to provide controlled admittance of desired substances into the processes. Practitioners have developed an entire class of fluid delivery systems which have fluid handling components removably attached to flow substrates containing fluid pathway conduits. The arrangement of such flow substrates establishes the flow sequence by which the fluid handling components provide the desired fluid conditioning and control. The interface between such flow substrates and removable fluid handling components is standardized and of few variations. Such fluid delivery system designs are often described as modular or surface mount systems. Representative applications of surface mount fluid delivery systems include gas panels used in semiconductor manufacturing equipment and sampling systems used in petrochemical refining. The many types of manufacturing equipment used to perform process steps making semiconductors are collectively referred to as tools. Embodiments of the present invention relate generally to fluid delivery systems for semiconductor processing and specifically to surface mount fluid delivery systems that are specifically well suited for use in extreme flow rate and/or high temperature applications where the process fluid is to be heated to a temperature above ambient. Aspects of the present invention are applicable to surface mount fluid delivery system designs whether of a localized nature or distributed around a semiconductor processing tool.

Industrial process fluid delivery systems have fluid pathway conduits fabricated from a material chosen according to its mechanical properties and considerations of potential chemical interaction with the fluid being delivered. Stainless steels are commonly chosen for corrosion resistance and robustness, but aluminum or brass may be suitable in some situations where cost and ease of fabrication are of greater concern. Fluid pathways may also be constructed from polymer materials in applications where possible ionic contamination of the fluid would preclude using metals. The method of sealingly joining the fluid handling components to the flow substrate fluid pathway conduits is usually standardized within a particular surface mount system design in order to minimize the number of distinct part types. Most joining methods use a deformable gasket interposed between the fluid component and the flow substrate to which it is attached. Gaskets may be simple elastomeric O-Rings or specialized metal sealing rings such as seen in U.S. Pat. Nos. 5,803,507 and 6,357,760. Providing controlled delivery of high purity fluids in semiconductor manufacturing equipment has been of concern since the beginning of the semiconductor electronics industry and the construction of fluid delivery systems using mostly metallic seals was an early development. One early example of a suitable bellows scaled valve is seen in U.S. Pat. No. 3,278,156, while the widely used VCR® fitting for joining fluid conduits is seen in U.S. Pat. No. 3,521,910, and a typical early diaphragm sealed valve is seen in U.S. Pat. No. 5,730,423 for example. The recent commercial interest in photovoltaic solar cell fabrication, which has less stringent purity requirements than needed for making the newest microprocessor devices, may bring a return to fluid delivery system using elastomeric seals.

A collection of fluid handling components assembled into a sequence intended for handling a single fluid species is frequently referred to as a gas stick. The equipment subsystem comprised of several gas sticks intended to deliver process fluid to a particular semiconductor processing chamber is often called a gas panel. During the 1990s several inventors attacked problems of gas panel maintainability and size by creating gas sticks wherein the general fluid flow path is comprised of passive metallic structures, containing the conduits through which process fluid moves, with valves and like active (and passive) fluid handling components removably attached thereto. The passive fluid flow path elements have been variously called manifolds, substrates, blocks, and the like, with some inconsistency even within the work of individual inventors. This disclosure chooses to use the terminology flow substrate or manifold to indicate fluid delivery system elements which contain passive fluid flow path(s) that may have other fluid handling devices mounted there upon.

### SUMMARY OF THE INVENTION

In one embodiment a delivery system can comprise a modular flow substrate comprising an i-Block and an i-Bridge. The i-Block can comprise a first i-Block conduit port, a second i-Block conduit port, a plurality of mounting apertures, a connection depression, at least one i-Block connection aperture and a fluid pathway extending between the first i-Block conduit port and the second i-Block conduit port. The i-Bridge can comprise an i-Bridge conduit port, a manifold connection conduit port, at least one connection aperture, at least one mounting aperture, a connection protrusion, and a fluid pathway extending between the i-Bridge conduit port and the manifold connection conduit port. The connection protrusion can be sized and configured to fit within the connection depression of the i-Block and the at least one connection aperture can be configured to match with the at least one i-Block connection aperture to allow for a fastener to secure the i-Bridge to the i-Block to form the modular flow substrate. The plurality of mounting apertures of the modular flow substrate can be configured to couple the modular flow substrate to at least one manifold and at least one fluid handling component.

### BRIEF DESCRIPTION OF THE DRAWINGS

FIG. 1 shows an embodiment of a manifold as seen in the prior art.

FIG. 2 shows a top view of an embodiment of a modular flow substrate coupled to a K1s manifold.

FIG. 3A shows a side view of the embodiment of the modular flow substrate coupled to a K1s manifold as seen in FIG. 2

FIG. 3B shows a cross-section view of the embodiment of the modular flow substrate coupled to the K1s manifold taken along line B-B seen in FIG. 3A.

FIG. 4 shows an isometric side view of the embodiment of the modular flow substrate coupled to the K1s manifold as seen in FIG. 2.

FIG. 5 shows a top view of an embodiment of a modular flow substrate coupled to an ICS manifold.

FIGS. 6A and 6B show a side view of the embodiment of the modular flow substrate coupled to the ICS manifold as seen in FIG. 5.

FIG. 6C shows a cross-section view of the embodiment of the modular flow substrate coupled to the ICS manifold taken along line B-B seen in FIG. 6B.

FIG. 7 shows an isometric side view of the embodiment of the modular flow substrate coupled to the ICS manifold as seen in FIG. 5.

FIG. 8A shows a separated isometric side view of an embodiment of a modular flow substrate and an ICS manifold.

FIG. 8B shows a separated isometric bottom side view of the embodiment of the modular flow substrate and the ICS manifold.

### DETAILED DESCRIPTION

Various embodiments are described herein of various apparatus and/or systems. Numerous specific details are set forth to provide a thorough understanding of the overall structure, function, manufacture, and/or use of the embodiments as described in the specification and illustrated in the accompanying drawings. It will be understood by those skilled in the art, however, that the embodiments may be practiced without such specific details. In other instances, well-known operations, components, and elements have not been described in detail so as not to obscure the embodiments described in the specification. Those of ordinary skill in the art will understand that the embodiments described and illustrated herein are non-limiting examples, and thus it can be appreciated that the specific structural and functional details disclosed herein may be representative and do not necessarily limit the scope of the embodiments, the scope of which is defined solely by the appended claims.

Reference throughout the specification to “various embodiments,” “some embodiments,” “one embodiment,” “an embodiment,” “an exemplary embodiment,” or the like, means that a particular feature, structure, or characteristic described in connection with the embodiment is included in at least one embodiment. Thus, appearances of the phrases “in various embodiments,” “in some embodiments,” “in one embodiment,” “in an embodiment,” “in an exemplary embodiment,” or the like, in places throughout the specification are not necessarily all referring to the same embodiment. Furthermore, the particular features, structures, or characteristics may be combined in any suitable manner in one or more embodiments. Thus, the particular features, structures, or characteristics illustrated or described in connection with one embodiment may be combined, in whole or in part, with the features structures, or characteristics of one or more other embodiments without limitation given that such combination is not illogical or non-functional.

Referring now to the drawings wherein like reference numerals are used to identify identical or similar components in the various views, an overview of the basic concept and design of the apparatus is shown schematically in FIG. 2.

Embodiments of the present invention are directed to a surface mount fluid delivery flow substrate that is specifically adapted for use in extreme flow rate and/or high temperature applications where the process fluid is to be heated (or cooled) to a temperature above (or below) that of the ambient environment. As used herein, and in the context of semiconductor process fluid delivery systems, the expression “extreme flow rate” corresponds to gas flow rates above approximately 50 SLM or below approximately 50 SCCM. A significant aspect of the present invention is the ability to fabricate flow substrates having fluid pathway conduits with a cross-sectional area (size) substantially larger or smaller than other surface mount architectures.

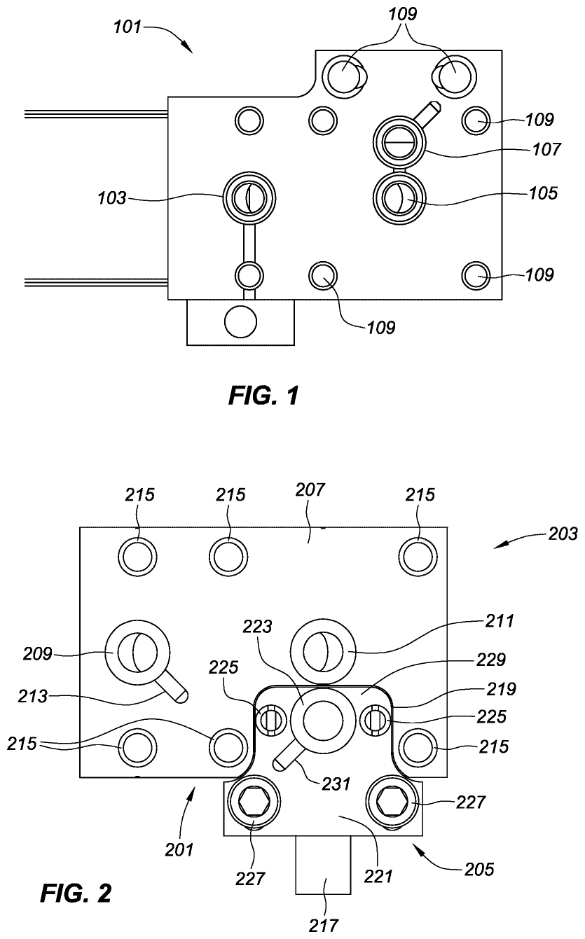

FIG. 1 illustrate an embodiment of a flow substrate 101 as seen in the prior art. The flow substrate 101 can be formed from a solid block of material with machined parts creating a first conduit port 103, a second conduit port 105, a third conduit port 107, and a plurality of mounting apertures 109. The flow substrate 101 can comprise a variety of configurations as may be required of various delivery flow systems. Fluid pathways can be made between conduit ports to move a fluid through the flow substrate. In some embodiments the flow substrate 101 can comprise multiple distinct fluid pathways. As seen in FIG. 1 the flow substrate 101 is created from a single block of material that is machined to create fluid pathways, mounting apertures, and other portions within the flow substrate. Additionally, excess material is removed from the flow substrate 101 to create the finished product. However, the materials used in the flow substrate 101 can be costly and excess material and machining costs are needed to make flow substrates in this manner. Additionally, the fluid pathways and other components of a flow substrate as seen in FIG. 1 are not able to be easily modified or changed after creation. In contrast, the separate component pieces of flow substrates as described herein limit the amount of material removed from the finished product and can allow for more modular design and creation of finished flow substrates.

While the flow substrate seen in FIG. 1 can allow for the direction of a fluid to be changed, the flow substrate of FIG. 1 require the specialized manufacture of these substrates for inclusion within an integrated subassembly. The flow substrate seen above can require larger blocks for initial machining and create additional waste material and manufacturing processes. In some of the embodiments described herein, 10% to 20% material savings can be achieved using the modular flow substrate in place of the prior art methods and materials. In contrast the modular flow substrate described below can minimize the number of number of fluid conduit ports and seals needed to build standardized fluid delivery sticks. Flow substrates for each fluid delivery stick can be fastened to a standardized bracket and each fluid delivery stick arrangement can be assembled and tested as an integrated subassembly. Use of the modular flow substrate described herein can allow for the direction of fluid to be changed without requiring more material width to create diverted ports. Additionally, the modular flow substrate can allow for the redirection of fluid or gas from the linear flow path without increasing the width of a standard fluid delivery system material while providing multiple flow direction paths diverted from the linear flow path. In some of the embodiments described herein, the linear flow path can comprise a plurality of i-Block components while the i-Bridge can be used to divert a fluid or gas away from the linear flow path. As a result, standardized components can be used for the linear flow path, while the diverting components can be added when the path needs to be diverted, but omitted from the linear flow path components when not needed. As a result, standardized materials can be used which can reduce manufacturing costs, wasted materials, the number of different components within the integrated subassembly and case assembly of the components. As seen and described throughout the application, the redirected fluid path from the linear flow path can comprise any three-dimensional direction without the need of a specialized linear flow path component for that section of the subassembly. Additionally, the prior art flow substrate illustrated in FIG. 1 needs to be welded to a manifold to such as an ICS manifold, K1s manifold, or other type. In contrast, as seen herein, the i-Bridge component of the modular flow substrate comprises at least one mounting aperture that can be used to fasten the i-Bridge to a manifold during assembly. This can decrease complexity of design within the system and case, removal, replacement, or reconfiguration before, during, or after installation. Further, as the components described herein are coupled through fasteners, dowels, screws or other types of joining devices, the assembly can more easily be done at a customer facility.

FIG. 2 illustrates one embodiment of a modular flow substrate 201 comprising an i-Block 203 and an i-Bridge 205 coupled to a K1s manifold 217. The i-Block 203 and the i-Bridge 205 can both comprise a solid block of material (such as stainless steel) and can comprise a component attachment surface to which another component, such as a fluid handling component (i.e. a valve, pressure transducer, filter, regulator, etc.) can be attached. The i-Block 203 can comprise an i-Block component attachment surface 207, a first i-Block conduit port 209, a second i-Block conduit port 211, a leak port 213, a plurality of mounting apertures 215, a connection depression 219, and a fluid pathway. In the illustrated embodiment the first i-Block conduit port 209 and the second i-Block conduit port 211 are joined by the fluid pathway. The i-Bridge 205 can comprise an i-Bridge component attachment surface 221, an i-Bridge conduit port 223, a fluid pathway extending from the i-Bridge conduit port, at least one connection aperture 225, at least one mounting aperture 227, a connection protrusion 229, a leak port 231, a weld cap, and a manifold connection conduit port. In the illustrated embodiment, the connection protrusion 229 of the i-Bridge can comprise a protrusion that extends from the i-Bridge and fits within the connection depression 219 of the i-Block 203 such that the two components of the modular flow substrate can be joined. In the illustrated embodiment, the i-Bridge 205 can comprise two connection apertures 225. The connection apertures 225 of the illustrated embodiment can be in line with the i-Bridge conduit port 223. In other embodiments, the i-Bridge can comprise two or more connection apertures that are asymmetrically placed in relation to the i-Bridge conduit port. In yet other embodiments, the i-Bridge can comprise a single connection aperture. The single connection aperture can be disposed adjacent the leak port of the i-Bridge conduit port, the single connection aperture can be placed opposite the leak port of the i-Bridge conduit port, or alternatively placed to allow the i-Block and i-Bridge to be coupled or otherwise connected to form the modular flow substrate. The i-Block 203 and the i-Bridge 205 can be joined or coupled by placement of a dowel or screw through the at least one connection aperture 225 to secure the i-Bridge 205 to the i-Block 203. In the illustrated embodiment, the corners of the i-Block depression 219 and the i-Bridge protrusion 229 are rounded. In other embodiments the corners can comprise right angles, flat edges, or other configurations to allow for case of placement of the i-Bridge within the i-Block to form the modular flow substrate during assembly. The i-Block conduit ports and i-Bridge conduit ports can be referred to generally as component conduit ports or conduit ports throughout the application.

In one embodiment, the component conduit ports of the i-Block and i-Bridge formed in the attachment surface can be arranged to fluidly communicate with fluid handling components having asymmetric port placement. In one embodiment the component mounting apertures can be formed in the attachment surface to receive a threaded fastener that can mount a fluid handling component in sealing engagement with the various component conduit ports of the modular flow substrate. In various embodiments, the modular flow substrate cam be formed from a suitable solid block of material such as stainless steel, 36L stainless steel, hastelloy, or where the application permits, from aluminum or brass. Where ionic contamination may be a concern, polymer materials may be used, and the flow substrate may be formed from other than a solid block of material (e.g., by molding). Additionally, other materials could be used to form the modular flow substrate blocks as would be known by one of ordinary skill in the art depending on pressure, flow rate, fluid material, material cost, manufacturability, or other variable.

The one or more component conduit ports can be formed in the component attachment surface of the modular flow substrate. In one embodiment, one of the conduit ports could be fluidly connected to the port (inlet or outlet) of a first fluid handling component, while a second conduit port could be fluidly connected to the port (outlet or inlet) of a second fluid handling component that is distinct form the first fluid handling component. In another embodiment, each of the conduit ports could be connected to the same fluid handling component. As seen in the illustrated embodiment, the modular flow substrate can comprise a pair of mounting apertures. In one embodiment, at least one of the mounting apertures can be internally threaded and can receive the threaded end of a fastener. Each fluid handling component can attached to one or more of the modular flow substrate or other flow substrate by four fasteners. In various embodiments, the fluid handling component could be attached to a single modular flow substrate or to two or more modular flow substrates. Each of the fluid handling components can be mounted to the at least one modular flow substrate in sealing engagement with one or more of the conduit ports. The fluid delivery system described herein can further include a seal at each conduit port of the i-Block, i-Bridge, fluid handling component, manifold, or other constituent part. The seal can ensure that the connection is fluid tight and reduce or eliminate leakage of any gas or liquid moving through the fluid delivery system.

As seen in FIG. 2, a leak port is associated with the pair of conduit ports in the i-Block component. The i-Bridge portion of the modular flow substrate also comprises a leak port associated with the conduit port. In some embodiments, a through hole can extend between a leak port associated with a conduit port and the attachment surface of the modular flow substrate, so that a faulty seal between a manifold and a flow substrate may be detected from above.

In some embodiments, a plurality of dowel pin apertures can be formed within one or more of the components of the modular flow substrate and can extend from the attachment surface through the modular flow substrate. Each of these dowel pin apertures can be configured to receive a dowel pin and can be used for backward compatibility with existing systems, and may be omitted where backwards compatibility is not an issue. The existing systems can comprise a K1s system or other type existing system

The plurality of counter-bored manifold mounting apertures can be formed in the component attachment surface of the components of the modular flow substrate and extend through a lower surface of the modular flow substrate. Each of these apertures can receive a threaded fastener that extends through the modular flow substrate and can be received in a threaded mounting aperture of a manifold. A conduit port of the manifold can be pulled into sealing engagement with a manifold connection conduit port of the i-Bridge of the modular flow substrate. In one embodiment, the manifold mounting apertures can use a fastener with a head sized suitably larger than the diameter of the aperture instead of using a counter-bore.

In one embodiment, the component conduit ports and manifold connection conduit ports can be machined in a cost-effective manner in which each has its corresponding axis of symmetry normal to the plane of a face of the flow substrate that is pierced. In this embodiment, the fluid pathways can be machined by piercing the plane of a face of the flow substrate or by machining along the length of the axis as illustrated in the i-Block connection attachment surface. In another embodiment, the component conduit ports, manifold connection conduit ports and fluid pathways can be machined in a cost-effective manner in which each has its corresponding axis of symmetry normal to the plane of a face of the flow substrate that is pierced. As seen throughout the application, respective component conduit ports can be formed by machining from the component attachment surface, the connection attachment surface, or a side surface into body of the modular flow substrate. The i-Bridge manifold connection conduit port can be formed by machining from the connection attachment surface of the i-Bridge into the body of the i-Bridge. The fluid pathway of the i-Block can be formed by machining into the body of the i-Block from the i-Block component attachment surface, the i-Block connection attachment surface, and a side face of the i-Block. After machining, the fluid pathway is sealed with a pathway cap that is welded in place to form a fluid tight seal. In the illustrated embodiment, each of the fluid pathways can be sealed with a respective pathway cap that is welded in place after machining to form a fluid tight seal. In an alternative embodiment where the fluid pathway is machined from a side of the modular flow substrate, the fluid pathway can be sealed with an end cap that is welded in place to form a fluid tight seal. In one embodiment, the pathway cap and/or end cap may be formed from a sheet of stainless steel by laser cutting, by water jet cutting, or other suitable techniques. In other embodiments, other materials such as brass or aluminum may be used, and where ionic contamination is a concern and the flow substrate is formed from a polymer material, the cap may be formed, for example, by molding a polymeric material that can later be epoxied into place. As seen in throughout the application, in some embodiments the fluid pathway of the i-Bridge can run in a plane that is orthogonal to an axis of a fluid pathway of the i-Block. In other embodiments, the fluid pathway of the i-Bridge can be angled relative to an axis of the fluid pathway of the i-Block. Additionally, other embodiments can comprise i-Bridge fluid pathways that can move in three dimensions, double back, loop, or otherwise be formed within the i-Bridge using the manufacturing processes described herein. In some embodiments, these additional sections of fluid pathway can be sealed with additional weld caps or through other processes as would be known to one of ordinary skill in the art. In the illustrated embodiments, an axis of the fluid pathway of the i-Block can be parallel to a longitudinal axis of the i-Block. In some embodiments, an axis of the fluid pathway of the i-Block can be congruent with a longitudinal axis of the i-Block. In yet other embodiments, an axis of the fluid pathway of the i-Block can be disposed at an angle relative to a longitudinal axis of the i-Block.

Additionally, the mounting apertures of the i-Block and i-Bridge as described herein can formed in the connection attachment surface of the respective modular flow substrate and can be internally threaded to receive a fastener that mounts the flow substrate to a fluid delivery stick component.

In the illustrated embodiments disclosed herein, at least a portion of the i-Bridge component of the modular flow substrate can extend beyond other portions of the modular flow substrate, such that the fasteners that fasten fluid handling components to the flow substrate and the fasteners that fasten the manifold to the flow substrate can all be accessible from a single direction, and without any interference from other structures.

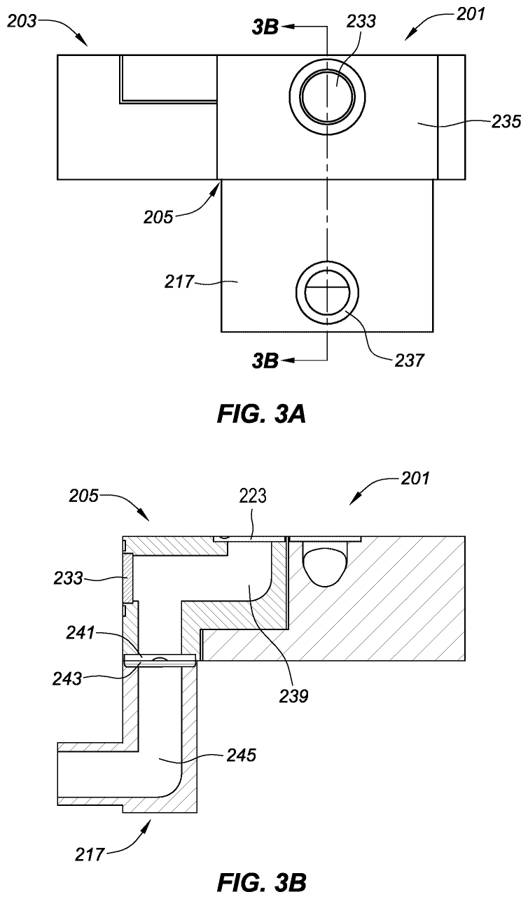

FIG. 3A illustrates a side view of the modular flow substrate 201 coupled to a K1s manifold 217 described in FIG. 2. The modular flow substrate 201 comprises the i-Block 203 and the i-Bridge 205. The i-Bridge 205 further comprises a weld cap 233 in an outward facing side face 235. The K1s manifold 217 further comprises a conduit port 237 that is fluidly coupled to the i-Bridge 205 as further seen in FIG. 3B. FIG. 3B illustrates a view taken along the B-B line of FIG. 3A. FIG. 3B further illustrates the fluid pathway formed when the modular flow substrate 201 is coupled to the K1s manifold 217. A fluid pathway is formed between the i-Bridge conduit port 223, the i-Bridge fluid pathway 239, the manifold connection conduit port 241, the manifold conduit port 243, and the K1s fluid pathway 245. The weld cap 233 can be secured to a side surface of the i-Bridge 205 to seal the machining opening used to create the fluid pathway. The fluid pathway can be created by the processes described herein.

While the illustrated embodiment shows an i-Bridge fluid pathway with 90 degree turns between the sections within the i-Bridge other configurations are possible within the component. In various embodiments, the fluid pathway can comprise a single pathway with no bends, additional bends within the fluid pathway, or alternative configurations. Additionally, while the illustrated embodiment discloses the i-Bridge fluid pathway 239 following a single plane normal to an outer surface of the i-Block, alternative embodiments can comprise i-Bridge fluid pathways that are angled relative to the outer surface of the i-Block. Additionally, other embodiments can comprise i-Bridge fluid pathways that can vary in three dimensions, double back, loop, or otherwise be formed within the i-Bridge using the manufacturing processes described herein. In some embodiments, these additional sections of fluid pathway can be sealed with additional weld caps or through other processes as would be known to one of ordinary skill in the art. In yet other embodiments, the manifold connection conduit port of the i-Bridge can be disposed where the weld cap is shown in FIG. 3B. In these embodiments, the fluid pathway of the i-Bridge would turn below the component attachment surface of the i-Bridge but would then continue sideways relative to the i-Block and exit the i-Bridge before turning in a downward direction as depicted in FIG. 3B. These embodiments would allow for lateral movement of a fluid or gas within the i-Bridge without requiring a manifold as described herein.

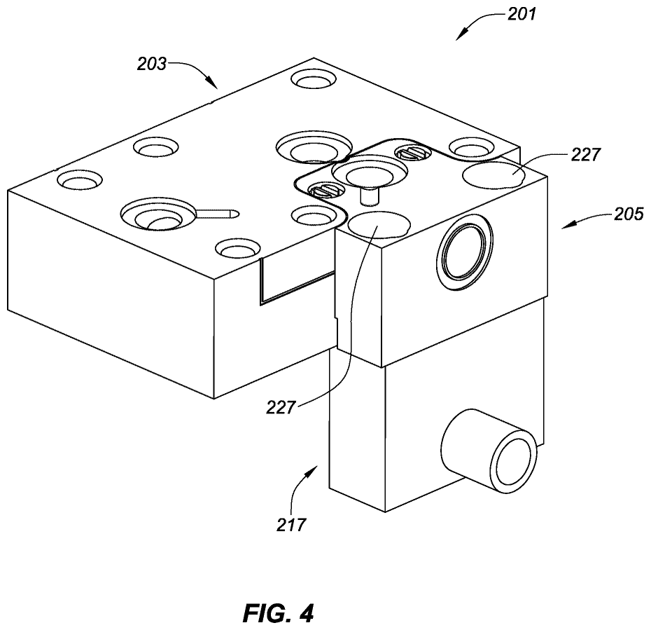

FIG. 4 depicts an isometric side view of the modular flow substrate 201 coupled to a K1s manifold 217 described in FIG. 2. The modular flow substrate 201 comprises an i-Block 203 and an i-Bridge 205 as described herein. The K1s manifold 217 is coupled to a lower surface of the i-Bridge 205 by fasteners within the mounting apertures 227 of the i-Bridge 205.

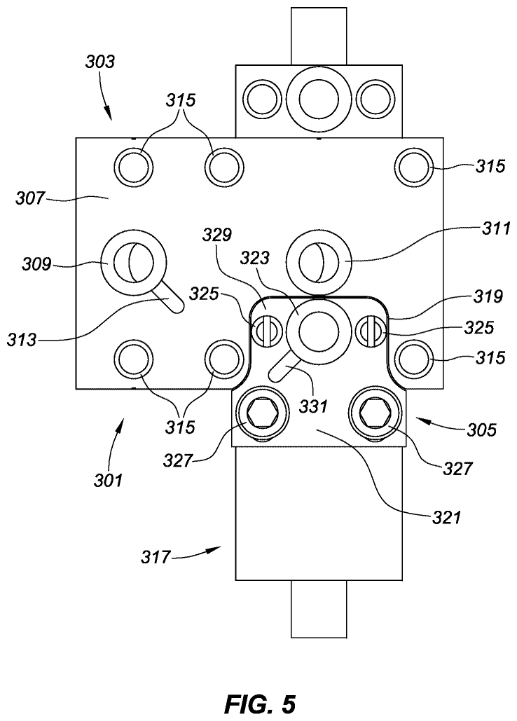

FIG. 5 depicts a modular flow substrate 301 comprising an i-Block 303 and an i-Bridge 305 coupled to an ICS manifold 317. The i-Block 303 and the i-Bridge 305 can both comprise a solid block of material (such as stainless steel) and can comprise a component attachment surface to which another component, such as a fluid handling component (i.e. a valve, pressure transducer, filter, regulator, etc.) can be attached. The i-Block 303 can comprise an i-Block component attachment surface 307, a first i-Block conduit port 309, a second i-Block conduit port 311, a leak port 313, a plurality of mounting apertures 315, a connection depression 319, and a fluid pathway. In the illustrated embodiment the first i-Block conduit port 309 and the second i-Block conduit port 311 are joined by the fluid pathway. The i-Bridge 303 can comprise an i-Bridge component attachment surface 321, an i-Bridge conduit port 323, a fluid pathway extending from the i-Bridge conduit port, at least one connection aperture 325, at least one mounting aperture 327, a connection protrusion 329, a leak port 331, a weld cap, and a manifold connection conduit port. In the illustrated embodiment, the connection protrusion 329 of the i-Bridge can comprise a protrusion that extends from the i-Bridge and fits within the connection depression 319 of the i-Block 303 such that the two components of the modular flow substrate can be joined. In the illustrated embodiment, the i-Bridge 305 can comprise two connection apertures 325. The connection apertures 325 of the illustrated embodiment can be in line with the i-Bridge conduit port 323. In other embodiments, the i-Bridge can comprise two or more connection apertures that are asymmetrically placed in relation to the i-Bridge conduit port. In yet other embodiments, the i-Bridge can comprise a single connection aperture. The single connection aperture can be disposed adjacent the leak port of the i-Bridge conduit port, the single connection aperture can be placed opposite the leak port of the i-Bridge conduit port, or alternatively placed to allow the i-Block and i-Bridge to be coupled or otherwise connected to form the modular flow substrate. The i-Block 303 and the i-Bridge 305 can be joined or coupled by placement of a dowel or screw through the at least one connection aperture 325 to secure the i-Bridge 305 to the i-Block 303. The ICS manifold 317 can comprise a manifold conduit port and at least one manifold mounting aperture. The manifold conduit port can be fluidly connected to the i-Bridge conduit port and direct fluid to or away from the i-Bridge component of the modular flow substrate. Additionally, the at least one manifold mounting aperture can be used to secure the ICS manifold to another component of the system or to mount an additional component to the ICS manifold.

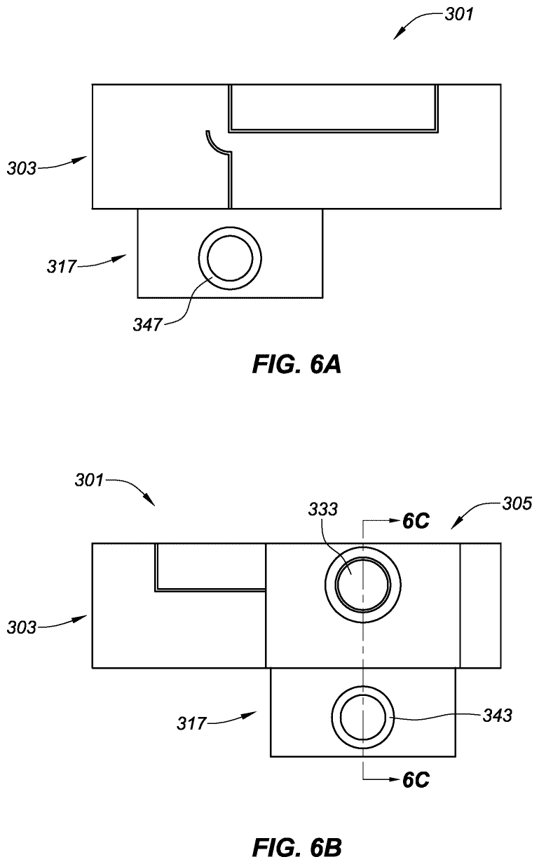

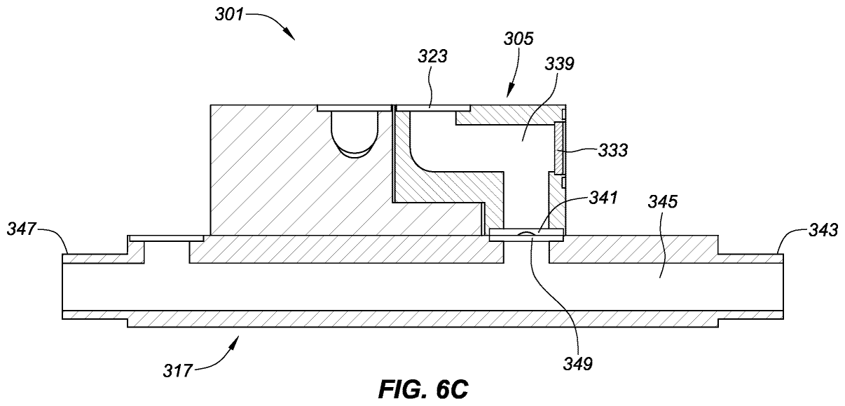

FIGS. 6A and 6B depict two side views of the modular flow substrate 301 comprising an i-Block 303 and an i-Bridge 305 coupled to an ICS manifold 317 as seen in FIG. 5. The weld cap 333 can be secured to a side surface of the i-Bridge 305 to seal the machining opening used to create the fluid pathway. The fluid pathway can be created by the processes described herein. The ICS manifold 317 further comprises a first conduit port 343 and a second conduit port 347 that are fluidly coupled to the i-Bridge 305 as further seen in FIG. 6C. FIG. 6C illustrates a view taken along the B-B line of FIG. 6B. FIG. 6C further illustrates the fluid pathway formed when the modular flow substrate 301 is coupled to the ICS manifold 317. A fluid pathway is formed between the i-Bridge conduit port 323, the i-Bridge fluid pathway 339, the manifold connection conduit port 341, the manifold third conduit port 349, the manifold first conduit port 343, the manifold second conduit port 347, and the ICS fluid pathway 345. The weld cap 333 can be secured to a side surface of the i-Bridge 305 to seal the machining opening used to create the fluid pathway. The fluid pathway can be created by the processes described herein.

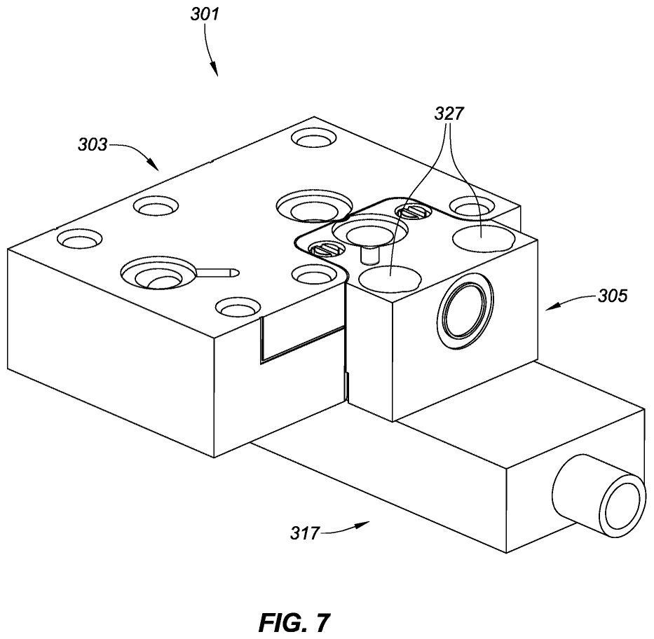

FIG. 7 depicts an isometric side view of the modular flow substrate 301 coupled to a ICS manifold 317 described in FIG. 5. The modular flow substrate 301 comprises an i-Block 303 and an i-Bridge 305 as described herein. The ICS manifold 317 is coupled to a lower surface of the i-Bridge 305 by fasteners within the mounting apertures 327 of the i-Bridge 305.

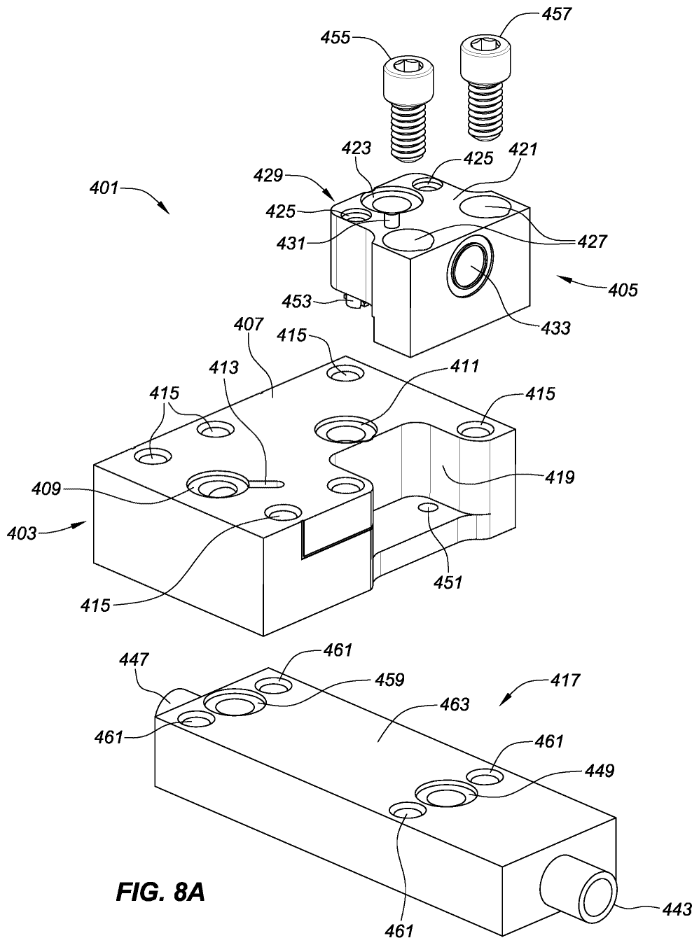

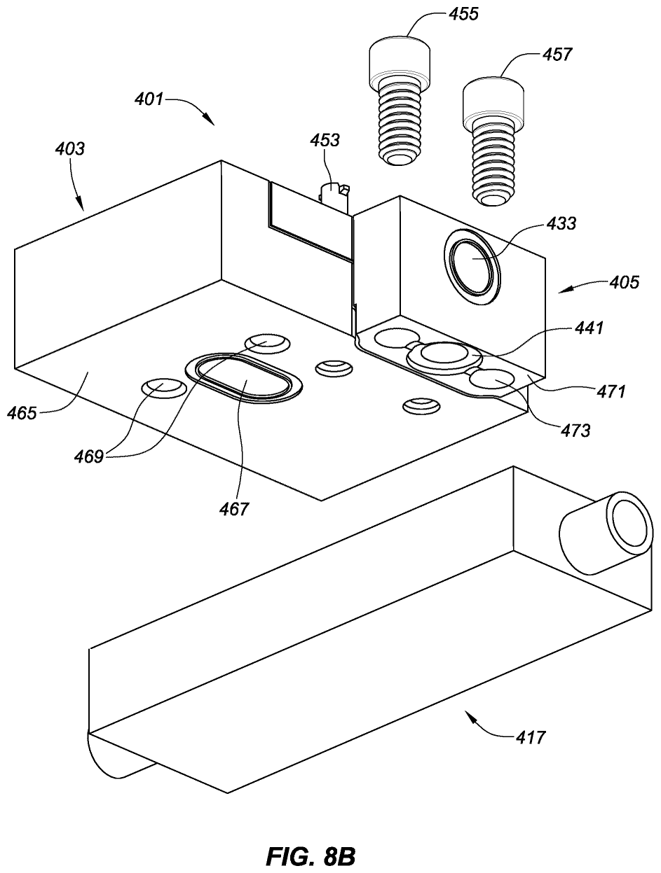

FIG. 8A illustrates a blown apart isometric side view of an embodiment of the modular flow substrate 401 coupled to a ICS manifold 417. As seen in this figures, the i-Block 403 and the i-Bridge 405 can both comprise a solid block of material and can comprise a component attachment surface to which another component can be attached as described herein. The i-Block 405 can comprise an i-Block component attachment surface 407, a first i-Block conduit port 409, a second i-Block conduit port 411, a leak port 413, a plurality of mounting apertures 415, a connection depression 419, at least one i-Block connection aperture 451, and a fluid pathway. The i-Bridge 405 can comprise an i-Bridge component attachment surface 421, an i-Bridge conduit port 423, a fluid pathway extending from the i-Bridge conduit port, at least one connection aperture 425, at least one alignment screw 453, at least one mounting aperture 427, a connection protrusion 429, a leak port 431, a weld cap 433, a first fastener 455, a second fastener 457, and a manifold connection conduit port. In the illustrated embodiment, the connection protrusion 429 of the i-Bridge can comprise a protrusion that extends from the i-Bridge and fits within the connection depression 419 the i-Block 403 such that the two components of the modular flow substrate can be joined. In the illustrated embodiment, the i-Bridge 405 can comprise two connection apertures 451. The at least one alignment screw 453 can be inserted through a connection aperture, extend through the i-Bridge 405, and have a distal end disposed within an i-Block connection aperture. The at least one alignment screw 453 can be sized and shaped to fit within the at least one i-Block connection port 451 to facilitate coupling the i-Bridge to the i-Block during assembly. In some embodiments, after the at least one alignment screw 453 has been positioned within the at least one i-Block connection aperture 451, additional processing such as welding or other securing mechanism can further secure the i-Block and the i-Bridge. The connection apertures 425 of the i-Bridge 405 in the illustrated embodiment can be in line with the i-Bridge conduit port 423. In other embodiments, the i-Bridge can comprise two or more connection apertures that are asymmetrically placed in relation to the i-Bridge conduit port. In yet other embodiments, the i-Bridge can comprise a single connection aperture. The single connection aperture can be disposed adjacent the leak port of the i-Bridge conduit port, the single connection aperture can be placed opposite the leak port of the i-Bridge conduit port, or alternatively placed to allow the i-Block and i-Bridge to be coupled or otherwise connected to form the modular flow substrate. The ICS manifold 417 can comprise a first manifold conduit port 449, a second manifold conduit port 443, a third manifold conduit port 447, a fourth manifold conduit port 459, at least one manifold mounting aperture 461, an upper surface 463, and a manifold fluid pathway connecting the first manifold conduit port 449, the second manifold conduit port 443 the third manifold conduit port 447, the fourth manifold conduit port 459, and any additional fluid exits of the ICS manifold. The first manifold conduit port 449 can be fluidly connected to and adjacent the i-Bridge conduit port and direct fluid to or away from the i-Bridge component of the modular flow substrate. Additionally, the at least one manifold mounting aperture can be used to secure the ICS manifold to another component of the system or to mount an additional component to the ICS manifold. In the illustrated embodiment, the first fastener 455 can be installed in a first of the at least one i-Bridge mounting aperture 427 and the second fastener 457 can be installed in a second of the at least one i-Bridge mounting aperture 427 to secure the i-Bridge 405 to the ICS manifold 417. As seen in FIG. 8A, the first fastener 455 and the second fastener 457 can be used to secure the i-Bridge 405 to the ICS manifold 417 by securing a distal end of each fastener within one of the mounting apertures of the ICS manifold 417.

FIG. 8B illustrates a partially blown apart bottom isometric view of the embodiment of the modular flow substrate 401 coupled to a ICS manifold 417 shown in FIG. 8A. As seen in FIG. 8B, the i-Block 403 further comprises an i-Block connection attachment surface 465, a pathway cap 467, and at least one attachment surface aperture 469. The pathway cap 467 can be used to fluidly seal a void created during manufacturing of a fluid pathway by sealing a portion of the i-Block connection attachment surface 465. The i-Block connection attachment surface 465 can be located adjacent to the ICS manifold 417 when the modular flow substrate is coupled to the ICS manifold 417. The at least one attachment surface aperture 469 can comprise an aperture as described herein to accept a fastener to secure another component to the i-Block 403. The i-Bridge 405 further comprises a manifold connection conduit port 441, an i-Bridge connection attachment surface 471, and at least one i-Bridge aperture exit 473. The first fastener 455 and the second fastener 457 can each pass through a respective one of the at least one i-Bridge aperture exit 473 to secure the i-Bridge 405 to the ICS manifold 417. As described herein, the manifold connection conduit port 441 can be sealingly coupled to a conduit port of the ICS manifold 417 to fluidly couple the i-Bridge 405 to the ICS manifold 417.

Additional information related to fluid delivery substrates can be found in U.S. Pat. No. 8,496,029 which is hereby incorporated by references as though fully set forth herein.

As shown and described herein and in the incorporated patents/application, a manifold or substrate body can be formed from a solid block of material and have an associated weld cap, each of which may be formed from a suitable material (such as stainless steel) in accordance with the intended use of the flow substrate. Primarily for cost reasons, but also for those applications that warrant the use of non-metallic materials (such as where ionic contamination is a concern), the body and/or weld cap of the manifold or flow substrate may also be formed (e.g., molded or machined) from polymeric materials, such as plastic. The use of other materials, such as plastic, permits the flow substrate to be particularly well suited to chemical delivery applications or biological applications where ionic contamination is a concern, and/or applications where cost is a concern.

The weld cap can be coupled with the manifold or substrate body using adhesive (i.e., glue) or similar mechanism (e.g., industrial metal bonding or non-metal bonding glue to create a bonded joint). The adhesive can be applied to the manifold or substrate body, the weld cap, or both using any application method (e.g., spraying, taping, dispensing, brush etc.). This configuration can be used for coupling metal, plastic, composite and other non-metal applications that are not conducive to welding. The adhesive can be selected to be resistant to the type of material flowing through the system to allow for a leak-free coupling (i.e., joint, connection, etc.). A benefit of using adhesive to couple the weld cap to the manifold or substrate body includes the ability to create a leak-free coupling that is resistant to the material flowing through the system without the time and cost associated with welding the weld cap to the manifold or substrate body.

It will be appreciated that details of the foregoing embodiments, given for purposes of illustration, are not to be construed as limiting the scope of the present disclosure. Although several embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure, which is further defined in the converted utility application and appended claims. Further, it is recognized that many embodiments may be conceived that do not achieve all the advantages of some embodiments, particularly preferred embodiments, yet the absence of a particular advantage shall not be construed to necessarily mean that such an embodiment is outside the scope of the present disclosure.

What is claimed is:

1. A delivery system comprising:
a modular flow substrate comprising an i-Block and an i-Bridge;
wherein the i-Block comprises a first i-Block conduit port, a second i-Block conduit port, a plurality of mounting apertures, a connection depression, at least one i-Block connection aperture and a fluid pathway extending between the first i-Block conduit port and the second i-Block conduit port;
wherein the i-Bridge comprises an i-Bridge conduit port, a manifold connection conduit port, at least one connection aperture, at least one mounting aperture, a connection protrusion, and a fluid pathway extending between the i-Bridge conduit port and the manifold connection conduit port, wherein the connection protrusion is sized and configured to fit within the connection depression of the i-Block and wherein the at least one connection aperture is configured to match with the at least one i-Block connection aperture to allow for a fastener to secure the i-Bridge to the i-Block to form the modular flow substrate,
wherein the plurality of mounting apertures of the modular flow substrate are configured to couple the modular flow substrate to at least one manifold and at least one fluid handling component.

2. The delivery system of claim 1, wherein the i-Bridge includes a component attachment surface.

3. The delivery system of claim 2, wherein a valve, pressure transducer, filter, or regulator is attached to the component attachment surface.

4. The delivery system of claim 1, wherein the at least one manifold is configured to be connected to the i-Bridge via the manifold connection conduit port.

5. The delivery system of claim 1, wherein the connection protrusion and the connection depression include correspondingly rounded edges.

6. The delivery system of claim 1, wherein the connection protrusion and the connection depression include correspondingly right angle edges.

7. The delivery system of claim 1, wherein the i-Bridge conduit port is defined within the connection protrusion.

8. The delivery system of claim 1, wherein the i-Bridge includes two connection apertures, and wherein the connection apertures are disposed in line with the i-Bridge conduit port.

9. The delivery system of claim 8, wherein the i-Bridge includes two connection apertures, and wherein the connection apertures are disposed asymmetrically in relation to the i-Bridge conduit port.

10. The delivery system of claim 1, wherein the modular flow substrate is formed from a solid block of material that includes stainless steel, hastelloy, aluminum, brass, or polymer.

11. The deliver system of claim 1, wherein the first and second i-Block conduit ports are defined in a component attachment surface of the i-Block.

12. The delivery system of claim 1, wherein the i-Bridge conduit port includes a leak port.

13. The delivery system of claim 1, wherein a K1S manifold is connected to a lower surface of the i-Bridge.
